(19) United States
(12) Patent Application Publication
(10) Pub. No.: US 2017/0018325 A1
(43) Pub. Date: Jan. 19, 2017

(54) SINTERABLE METAL PARTICLES AND THE USE THEREOF IN ELECTRONICS APPLICATIONS

(71) Applicants: HENKEL AG & CO. KGAA, Duesseldorf (DE); HENKEL IP & HOLDING GMBH, Duesseldorf (DE)

(72) Inventors: Liesbeth THEUNISSEN, Wilsele (BE); Anja Henckens, Zonhoven (BE); Stanislas Petrash, Whippany, NJ (US); Kang Wei Chou, 2° Sabadell (ES)

(21) Appl. No.: 15/244,081

(22) Filed: Aug. 23, 2016

Related U.S. Application Data
(63) Continuation of application No. PCT/US2015/016107, filed on Feb. 17, 2015.
(60) Provisional application No. 61/943,516, filed on Feb. 24, 2014.

(51) Int. Cl. H01B 1/22; H05K 3/32; H05K 1/09

(52) U.S. Cl. CPC H01B 1/22; H05K 1/092; H05K 3/321

(57) ABSTRACT

Provided herein are sinterable metal particles and compositions containing same. Such compositions can be used in a variety of ways, i.e., by replacing solders as die attach materials. The resulting sintered compositions are useful as a replacement for solder in conventional semiconductor assembly, and provide enhanced thermal and electrical conductivity in high power devices. Thus, invention compositions provide an alternative to nano-particulate metals that must be subjected to mechanical force during cure.

### FIELD OF THE INVENTION

The present invention relates to sinterable metal particles, and various uses thereof. In one aspect, the invention relates to compositions containing sinterable metal particles. In another aspect, the invention relates to methods for adhering metal particles to a metallic substrate. In yet another aspect, the invention relates to methods for improving the adhesion of metal components to a metallic substrate.

### BACKGROUND OF THE INVENTION

In order to meet guidelines promulgated by various regulatory authorities (for example, the Restriction of Hazardous Substances (RoHS) regulation requires the complete elimination of Pb from electronic appliances), the die attach market is looking for alternatives to lead-containing solder. Current candidate solders like Bi-alloys, Zn-alloys, and Au—Sn alloys are of low interest because of the many limitations thereof, e.g., poor electrical and thermal conductivities, brittleness, poor processability, poor corrosion resistance, high costs, and the like.

Another trend in the market is the emergence of silicon carbide technologies to replace silicon technologies. To achieve higher performance, silicon carbide technologies operate at significantly higher temperatures, power, and voltages than do silicon technologies. Candidate solders referred to above cannot be applied at temperatures above 250° C. Thus, in addition to the disadvantages of lead-free solders referred to above, lead-free solders have a lower operating temperature window compared to lead-containing solder.

Sintering is the welding/bonding together of particles of metal by applying heat below the melting point of the metal. The driving force is the change in free energy as a result of the decrease in surface area and surface free energy. At the sintering temperature the diffusion process causes necks to form, which lead to the growth of these contact points. After completion of the sintering process, the neighboring metal particles are held together by cold welds. In order to have good adhesion, thermal and electrical properties, the different particles have to be almost completely merged together, resulting in a very dense structure of metal with limited amount of pores.

Most work with sintering of metal particles has been conducted on nano-particles. Work with nano particles reveals that such materials sinter at temperatures lower than conventional metal flakes because of their higher surface area, which drives the sintering. Unfortunately, the material which is formed after sintering at elevated temperatures remains porous and brittle. The presence of pores can cause voids in the conductive composition, which can lead to failure of the semiconductor or microelectronic device in which the filler particle is used. To overcome the presence of pores, and increase bond strength, nano-particulate metals are commonly sintered at elevated temperatures while being subjected to mechanical force so as to eliminate pores and attain sufficient densification so as to be suitable for use in semiconductor manufacture. Another issue with the use of nano-particulate metals is the potential health and environmental challenges presented thereby.

### SUMMARY OF THE INVENTION

In accordance with one aspect of the present invention, there are provided compositions comprising sinterable metal particles. Such compositions can be used in a variety of ways, i.e., by replacing solders in die attach applications or by replacing solders as a die attach material. The resulting sintered compositions are useful as a replacement for solder in conventional semiconductor assembly, and provide enhanced conductivity in high power devices. Thus, invention compositions provide an alternative to nano-particulate metals that must be subjected to mechanical force during cure.

Thus, in accordance with one aspect of the current invention, there are provided compositions comprising metal particles with defined properties. Such compositions show good sintering capabilities, creation of sintered material having reduced occurrence of pores therein, and which do not necessarily need to be sintered under excessive heat and the application of mechanical force to create a dense structure, which results in the formation of more connection points with the interface and strong bonds.

Specifically, it has been found that metal particles which have the following combination of properties will also have good sintering properties:
1. Particles need to be of a certain crystallite size (crystallite size can be obtained, for example, from X-ray analyses via the Rietveld refinement method). Since factors other than crystalline size (crystal dislocations, grain boundaries, microstresses, etc.) can also partially contribute to peak broadening, it was elected to work with the factor yr (which is an average value, deduced from the peak width of diffraction peaks (fitted with a Lorentzian function), divided by the position of the peak for the different peaks.
2. The sinterable particles need to be anisotropic with respect to the crystallographic direction. Crystal anisotropy can be defined as the variation of shape, physical or chemical properties of crystalline material in directions related to the principal axis (or crystalline planes) of its crystal lattice. Materials with such anisotropic properties have been observed to exhibit preferential orientation relative to each other. Such orientation of multiple particles provides a good starting point for sintering since relating planes are oriented parallel to each other and will readily sinter. An exemplary method to determine if a crystal is anisotropic involves comparing the relative intensity of certain diffraction peaks with those for fully isotropic material (see e.g. Yugang Sun & Younan Xia, Science, Vol. 298, 2002, pp. 2176-79). In addition preferably over 50% of the particles exhibit such anisotropy, especially where such anisotropy is in the same crystallographic direction.
3. Particles should have a degree of crystallinity of at least 50%.

### BRIEF DESCRIPTION OF THE FIGURES

FIG. 1 shows the raw X-ray diffraction data for three exemplary particulate silver samples, as representative of a typical sinterable metal.

FIG. 2 shows plots of the peak widths for seven different samples, as a function of every peak position. Note that samples that perform well in the die-shear test fall into a lower “band”, which corresponds to generally narrower peaks and, therefore, according to the Scherrer's equation, generally larger crystals.

FIG. 3 shows the plot of this “psi” parameter for all samples analyzed.

### DETAILED DESCRIPTION OF THE INVENTION

In accordance with the present invention, there are provided compositions comprising:
sinterable metal particles dispersed in
a suitable carrier therefor,
wherein at least a portion of said metal particles are characterized by:
   having a Ψ value, as defined by X-ray diffraction, <0.0020,
   having at least 50% degree of crystallinity, and
   being anisotropic with respect to crystallographic direction.

Sinterable metal particles contemplated for use herein include Ag, Cu, Au, Pd, Ni, In, Sn, Zn, Li, Mg, Al, Mo, and the like, as well as mixtures of any two or more thereof. In some embodiments, the sinterable metal particles are silver.

The Ψ value is employed herein to express the broadening of the diffraction peak (which is due to contribution from both the instrument and the specimen). For purposes of this application, “Specimen Broadening” is separated from “Instrument Broadening”.

The customarily used term for the function that describes the shape of the diffraction peak is the Profile Shape Function (PSF). For purposes of the present disclosure, it was elected to use the Lorentzian function herein to fit the peaks.

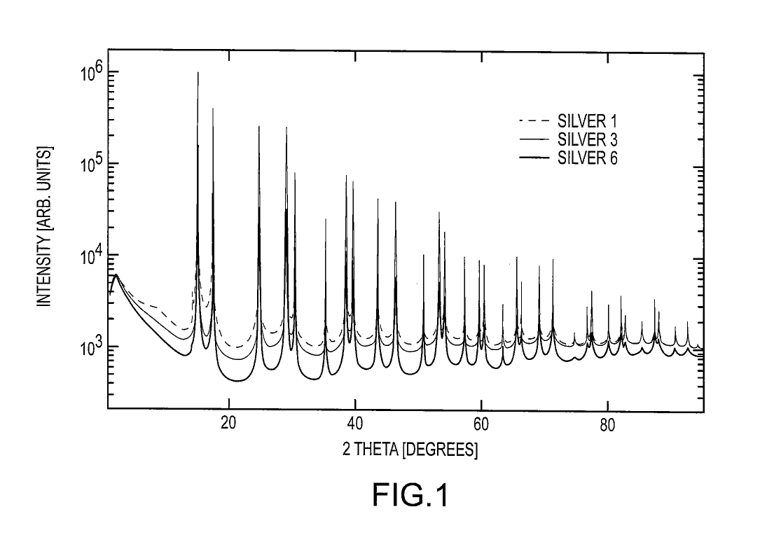

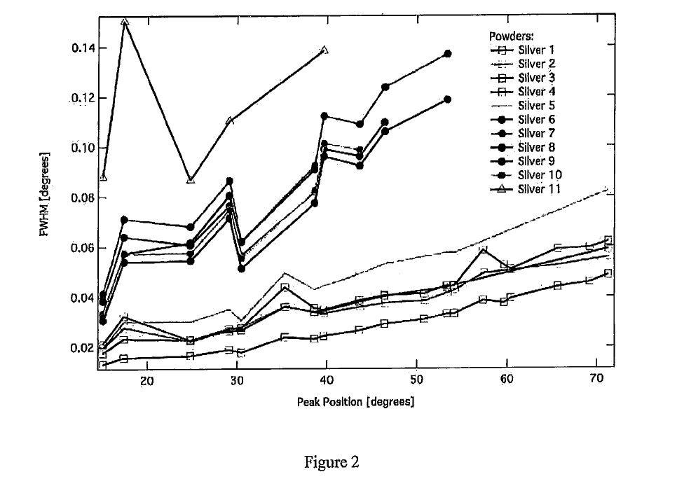

Thus, determination of the “psi” parameter from the raw data is carried out by first obtaining raw X-ray diffraction data for exemplary materials (see, for example, FIG. 1). Then peak widths are obtained for all samples (see, for example, FIG. 2).

To simplify sample characterization, one can define a “psi” parameter, as a peak width divided by its peak position (so the value is dimensionless). One can then calculate the average of “psi” for each peak and arrive at a final average value.

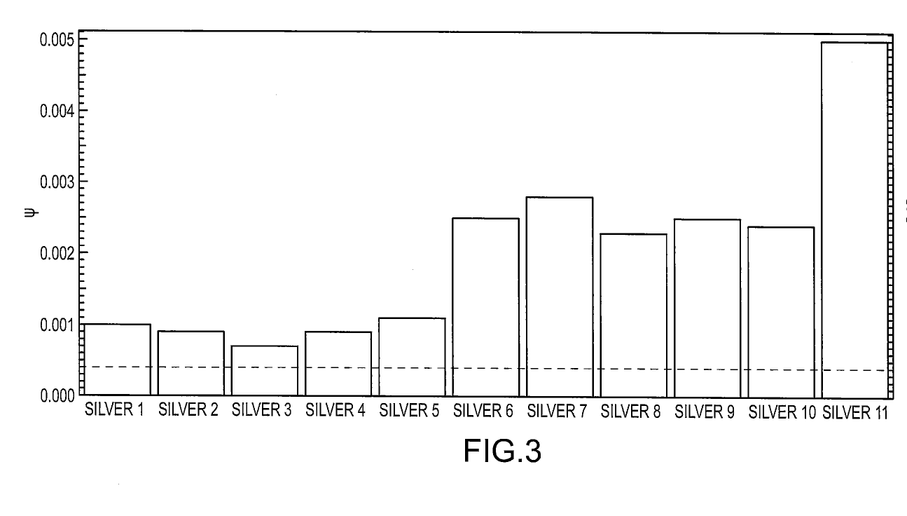

FIG. 3 shows the plot of this “psi” parameter for all the samples analyzed.

Note that the “psi” for each sample still represents the contribution from both the Instrument Broadening and the Specimen Broadening. The dotted line in FIG. 3 is the contribution to the “psi” from the instrument (which is a constant, obtained from the analysis of the reference NAC crystals on the same instrument as the rest of the samples).

Next the total “psi” factor and the “psi”-star (which represents the broadening of the diffraction peaks due to the specimen only) are compared. A threshold of 0.002 separates the well-performing samples from poorly-performing ones.

Metal particles contemplated for use herein have at least 50% degree of crystallinity. In some embodiments, metal particles contemplated for use herein have at least 60% degree of crystallinity; in some embodiments, metal particles contemplated for use herein have at least 70% degree of crystallinity; in some embodiments, metal particles contemplated for use herein have at least 80% degree of crystallinity; in some embodiments, metal particles contemplated for use herein have at least 90% degree of crystallinity; in some embodiments, metal particles contemplated for use herein have at least 95% degree of crystallinity; in some embodiments, metal particles contemplated for use herein have at least 98% degree of crystallinity; in some embodiments, metal particles contemplated for use herein have at least 99% degree of crystallinity; in some embodiments, metal particles contemplated for use herein have substantially 100% degree of crystallinity.

As used herein, crystal anisotropy refers to the variation of physical or chemical properties of crystalline material in directions related to principal axis (or crystalline planes) of its crystal lattice. Numerous methods are available for determining anisotropy of crystals, including, for example, optical, magnetic, electrical or X-ray diffraction methods. One of the latter methods of differentiation of crystal anisotropy of silvers in particular, is referred to by Yugang Sun & Younan Xia, Science, Vol. 298, 2002, pp. 2176-79:
It is worth noting that the ratio between the intensities of the (200) and (111) diffraction peaks was higher than the conventional value (0.67 versus 0.4), indicating that our nanocubes were abundant in {100} facets, and thus their {100} planes tended to be preferentially oriented (or textured) parallel to the surface of the supporting substrate (26). The ratio between the intensities of the (220) and (111) peaks was also slightly higher than the conventional value (0.33 versus 0.25) because of the relative abundance of {110} facets on the surfaces of our silver nanocubes.

In accordance with certain aspects of the present invention, at least 20% of the metal particles in invention compositions are anisotropic with respect to crystallographic direction. In some embodiments, at least 50% of the metal particles in invention compositions are anisotropic with respect to crystallographic direction. In some embodiments, at least 60% of the metal particles in invention compositions are anisotropic with respect to crystallographic direction. In some embodiments, at least 80% of the metal particles in invention compositions are anisotropic with respect to crystallographic direction. In some embodiments, at least 95% of the metal particles in invention compositions are anisotropic with respect to crystallographic direction.

Sinterable metal particles typically comprise at least about 20 weight percent of the composition, up to about 98 weight percent thereof. In some embodiments, sinterable metal particles comprise about 40 up to about 98 weight percent of compositions according to the present invention; in some embodiments, sinterable metal particles comprise in the range of about 85 up to about 97 weight percent of compositions according to the present invention.

In order to realize the benefits imparted by the present invention, it is only necessary that a portion of the metal particles contemplated for use herein satisfy the plurality of criteria set forth herein. Thus, in some embodiments, at least 5% of the metal particles employed will meet each of the criteria set forth herein. In some embodiments, at least 10% of the metal particles employed will meet each of the criteria set forth herein. In some embodiments, at least 20% of the metal particles employed will meet each of the criteria set forth herein. In some embodiments, at least 30% of the metal particles employed will meet each of the criteria set forth herein. In some embodiments, at least 40% of the metal particles employed will meet each of the criteria set forth herein. In some embodiments, at least 50% of the metal particles employed will meet each of the criteria set forth herein. In some embodiments, at least 60% of the metal particles employed will meet each of the criteria set forth herein. In some embodiments, at least 70% of the metal particles employed will meet each of the criteria set forth herein. In some embodiments, at least 80% of the metal particles employed will meet each of the criteria set forth herein. In some embodiments, at least 90% of the metal particles employed will meet each of the criteria set forth herein. In some embodiments, at least 95% of the metal particles employed will meet each of the criteria set forth herein. In some embodiments, at least 98% of the metal particles employed will meet each of the criteria set forth herein. In some embodiments, substantially all of the metal particles employed will meet each of the criteria set forth herein.

Sinterable metal particles contemplated for use in the practice of the present invention typically have a particle size in the range of about 100 nanometers up to about 15 micrometers. In certain embodiments, sinterable metal particles contemplated for use herein have a particle size of at least 200 nanometers. In other embodiments of the present invention, sinterable metal particles contemplated for use herein have a particle size of at least 250 nanometers. In certain embodiments, sinterable metal particles contemplated for use herein have a particle size of at least 300 nanometers. Thus, in some embodiments, sinterable metal particles having a particle size in the range of about 200 nm up to 10 micrometers are contemplated for use herein; in some embodiments, sinterable metal particles having a particle size in the range of about 250 nm up to 10 micrometers are contemplated for use herein; in some embodiments, sinterable metal particles having a particle size in the range of about 300 nm up to 10 micrometers are contemplated for use herein; in some embodiments, sinterable metal particles having a particle size in the range of about 200 nm up to 5 micrometers are contemplated for use herein; in some embodiments, sinterable metal particles having a particle size in the range of about 250 nm up to 5 micrometers are contemplated for use herein; in some embodiments, sinterable metal particles having a particle size in the range of about 300 nm up to 5 micrometers are contemplated for use herein; in some embodiments, sinterable metal particles having a particle size in the range of about 200 nm up to 1 micrometer are contemplated for use herein; in some embodiments, sinterable metal particles having a particle size in the range of about 250 nm up to 1 micrometer are contemplated for use herein; in some embodiments, sinterable metal particles having a particle size in the range of about 300 nm up to 1 micrometer are contemplated for use herein.

Sinterable metal particles contemplated for use herein can exist in a variety of shapes, e.g., as substantially spherical particles, as irregular shaped particles, oblong particles, flakes (e.g., thin, flat, single crystal flakes), and the like. Sinterable metal particles contemplated for use herein include silver coated/plated particulate, wherein the underlying particulate can be any of a variety of materials, so long as the silver coating/plating substantially coats the underlying particulate, such that the resulting composition comprises a thermoplastic matrix having silver-covered particles distributed throughout.

Carriers contemplated for use herein include alcohols, aromatic hydrocarbons, saturated hydrocarbons, chlorinated hydrocarbons, ethers, polyols, esters, dibasic esters, kerosene, high boiling alcohols and esters thereof, glycol ethers, ketones, amides, heteroaromatic compounds, and the like, as well as mixtures of any two or more thereof.

Exemplary alcohols contemplated for use herein include t-butyl alcohol, 1-methoxy-2-propanol, diacetone alcohol, dipropylene glycol, ethylene glycol, diethylene glycol, triethylene glycol, hexylene glycol, octanediol, 2-ethyl-1,3-hexanediol, tridecanol, 1,2-octanediol, butyldiglycol, alpha-terpineol, beta-terpineol, and the like.

Exemplary aromatic hydrocarbons contemplated for use herein include benzene, toluene, xylene, and the like.

Exemplary saturated hydrocarbons contemplated for use herein include hexane, cyclohexane, heptane, tetradecane, and the like.

Exemplary chlorinated hydrocarbons contemplated for use herein include dichloroethane, trichloroethylene, chloroform, dichloromethane, and the like.

Exemplary ethers contemplated for use herein include diethyl ether, tetrahydrofuran, dioxane, and the like.

Exemplary esters contemplated for use herein include ethyl acetate, butyl acetate, methoxy propyl acetate, 2-(2-butoxyethoxy)ethyl acetate, 2,2,4-trimetyl-1,3-pentanediol diisobutyrate, 1,2-propylene carbonate, carbitol acetate, butyl carbitol, butyl carbitol acetate, ethyl carbitol acetate, dibutylphthalate, and the like.

Exemplary ketones contemplated for use herein include acetone, methyl ethyl ketone, and the like.

The amount of carrier contemplated for use in accordance with the present invention can vary widely, typically falling in the range of about 2 up to about 80 weight percent of the composition. In certain embodiments, the amount of carrier falls in the range of about 2 up to 60 weight percent of the total composition. In some embodiments, the amount of carrier falls in the range of about 3 up to about 15 weight percent of the total composition.

In accordance with another embodiment of the present invention, there are provided compositions comprising:
sinterable metal particles dispersed in
a suitable carrier therefor,
wherein substantially all of the metal particles in the composition are characterized by:
   having a Ψ value, as defined by X-ray diffraction, <0.0020,
   having at least 50% degree of crystallinity, and
   being anisotropic with respect to crystallographic direction.

In accordance with yet another embodiment of the present invention, there are provided methods of preparing conductive networks, said method comprising:
applying a composition as described herein to a suitable substrate to bond a suitable component thereto, and thereafter
sintering said composition.

A wide variety of substrates are contemplated for use herein, e.g., a ceramic layer, optionally having a metallic finish thereon.

Suitable components contemplated for use herein include bare dies, eg. metal-oxide-semiconductor field-effect transistors (MOSFET), insulated-gate bipolar transistors (IGBT), diodes, light emitting diodes (LED), and the like.

A particular advantage of compositions according to the present invention is that they can be sintered at relatively low temperatures, e.g., in some embodiments at temperatures in the range of about 100-350° C. When sintered at such temperatures, it is contemplated that the composition be exposed to sintering conditions for a time in the range of 0.5 up to about 120 minutes.

In certain embodiments, it is contemplated that sintering may be carried out at a temperature no greater than about 300° C. (typically in the range of about 150-300° C.). When sintered at such temperatures, it is contemplated that the composition be exposed to sintering conditions for a time in the range of 0.1 up to about 2 hours.

In accordance with yet another embodiment of the present invention, there are provided conductive networks comprising a sintered array of sinterable metal particles having a resistivity of no greater than 1×10⁻⁴ Ohms·cm. In accordance with still another embodiment of the present invention, there are provided conductive networks comprising a sintered array of sinterable metal particles having a resistivity of no greater than 1×10⁻⁵ Ohms·cm.

Such conductive networks are typically applied to a substrate, and display substantial adhesion thereto. Adhesion between the substrate and a suitable component provided by the conductive network can be determined in a variety of ways, e.g., by die shear strength (DSS) measurements, tensile lap shear strength (TLSS) measurements, and the like. In accordance with the present invention, a die shear strength adhesion of at least 3 kg/mm² between the substrate and the bonded components is typically obtained.

In accordance with still another embodiment of the present invention, there are provided methods for adhering sinterable metal particles to a metallic substrate, said method comprising:
applying a composition as described herein to said substrate, and thereafter sintering said composition.

In accordance with this embodiment of the present invention, sintering under low temperature (e.g., at a temperature no greater than about 150° C.; or at a temperature no greater than about 120° C.) is contemplated.

Suitable substrates having a metallic finish thereon include ceramic materials such as silicon nitride (SiN), Alumina (Al₂O₃), aluminium nitride (AlN), beryllium oxide (BeO), aluminum hydroxide, silica, vermiculite, mica, wollastonite, calcium carbonate, titania, sand, glass, barium sulfate, zirconium, carbon black, and the like.

Metallic finish can be applied to the above-described ceramic materials in a variety of ways, employing metals selected from Ag, Cu, Au, Pd, Ni, Pt, Al, and the like.

In accordance with yet another embodiment of the present invention, there are provided methods for improving the adhesion of metal particle-filled formulations to metallic substrates, said methods comprising employing as at least a portion of said metal filler sinterable metallic particles characterized as:
having a Ψ value, as defined by X-ray diffraction, <0.0020,
having at least a portion thereof in anisotropic form with respect to crystallographic direction, and
having at least 50% degree of crystallinity.

In accordance with still another embodiment of the present invention, there are provided methods for identifying metallic powders which are sinterable, said methods comprising identifying as sinterable those metallic powders which have:
a Ψ value of <0.0020,
at least 50% degree of crystallinity, and
at least a portion of said metal particles are anisotropic with respect to crystallographic direction.

In accordance with a still further embodiment of the present invention, there are provided methods for determining whether metallic powders are sinterable, said methods comprising
measuring the Ψ value thereof, the degree of crystallinity thereof and whether or not the sample is anisotropic, and
identifying as sinterable those metallic powders which have:
   a Ψ value of <0.0020,
   at least 50% degree of crystallinity, and
   at least a portion of said metal particles are anisotropic with respect to crystallographic direction.

Various aspects of the present invention are illustrated by the following non-limiting examples. The examples are for illustrative purposes and are not a limitation on any practice of the present invention. It will be understood that variations and modifications can be made without departing from the spirit and scope of the invention. One of ordinary skill in the art readily knows how to synthesize or commercially obtain the reagents and components described herein.

### EXAMPLES

### Example 1

Table 1 identifies several different silver particulate materials which were employed herein. All silver materials are sub-micron to micron sized silvers, except the final entry, which is a nano-sized silver. The same carrier was employed for each of the silvers. The key performance properties are adhesion (DSS and TLSS) and bulk conductivity (as indicated by the volume resistivity (Vr)), see Table 1.

TABLE 1

| | Ag properties determined | | | | | | | | |
|---|---|---|---|---|---|---|---|---|---|
| | by XRD measurements | | | Ag sintering - | | Ag sintering - | | Ag | |
| | | Intensity | | no pressure - Ag DBC | | no pressure - Cu DBC | | DBC | |
| | | 200/Intensity | | DDS - | DDS - | DDS - | DSS - | TLSS - | Vr - |
| silver | Ψ | 111 | Crystallinity | kg | kg/mm2 | kg | kg/mm2 | MPa | Ohm/cm |
| Silver 1 | 0.0010 | 0.480 | 82% | 5.8 | 0.65 | 6.6 | 0.73 | 4.6 | 1.6E−05 |
| Silver 2 | 0.0009 | 0.419 | 97% | 4.9 | 0.54 | 3.8 | 0.42 | 3.9 | |
| Silver 3 | 0.0007 | 0.516 | 99% | 69.8 | 7.76 | 34.7 | 3.86 | 16.0 | 4.1E−06 |
| Silver 4 | 0.0009 | 0.727 | | no wetting | no wetting | no wetting | no wetting | 13.4 | |
| | | | | DBC | DBC | DBC | DBC | | |
| Silver 5 | 0.0011 | 0.574 | | no wetting | no wetting | no wetting | no wetting | 13.3 | |
| | | | | DBC | DBC | DBC | DBC | | |
| Silver 6 | 0.0025 | 0.514 | | 23.7 | 2.63 | 28.0 | 3.11 | 11.7 | 5.1E−06 |
| Silver 7 | 0.0028 | 0.500 | | 39.9 | 4.44 | 24.8 | 2.76 | 10.4 | 3.9E−06 |
| Silver 8 | 0.0023 | 0.498 | 100% | 14.4 | 1.60 | 12.2 | 1.36 | 8.4 | |
| Silver 9 | 0.0025 | 0.498 | | No wetting | No wetting | No wetting | No wetting | 7.9 | |
| | | | | DBC | DBC | DBC | DBC | | |
| Silver 10 | 0.0024 | 0.470 | 95% | 43.8 | 4.87 | 15.5 | 1.72 | 10.3 | 4.5E−06 |
| Silver 11 | 0.0050 | | | No wetting | No wetting | No wetting | No wetting | 4.1 | |
| | | | | DBC | DBC | DBC | DBC | | |

For all examples, the surface finish of both the die and the DBC (direct bonded copper) substrate is silver. Test dies were 3 by 3 mm². The silver paste was screen printed in a 75 micron thick layer onto the DBC substrate and a die was placed manually onto the silver paste. Build-up was sintered pressure-less in an oven which was ramped from room temperature to 250° C. in 15 minutes, with the temperature being maintained for 1 hour at 250° C.

For the TLSS (tensile lap shear strength) test, two Ag plated DBCs were sintered together by the silver paste. DBC overlap is 0.8 by 0.8 cm².

An exemplary sinterable silver particulate shows an excellent die shear strength (DSS) value of 7.8 kg/mm² after pressure-less sintering. The TLSS of the same silver particulate, when sintered pressure-less, is 16 MPa. This indicates that this preferred silver particulate material builds-up a strong connection with the Ag-DBC interphase.

All other silver particulates have lower adhesion values. Bulk conductivity is 4·10⁻⁶ Ohm·cm. Morphological analysis of the preferred sintered silver particulate shows a dense sintered structure. Sintering occurred face-to-face and edge-to-edge. Several other sinterable metal particles which meet the criteria set forth herein performed comparably to the preferred material described above.

The lowest performing silver had a DSS of only 0.65 kg/mm² and a TLSS of only 4.6 MPa. Conductivity is only 1.6 10⁻⁵ Ohm·cm. Morphological analysis of this silver particulate which falls outside the requirements contemplated herein shows only limited connection points and thin connection points between the different initial particles.

An intermediate performing silver particulate material had a DSS of only about 2.6 kg/mm² and a TLSS of 11.7 MPa. Conductivity is 5 10⁻⁶ Ohm·cm. Morphological analysis reveals that sintering occurs edge-to-edge but less phase-to-phase.

The nano size silver investigated herein shows very low TLSS values of 4.1 MPa. Morphological analysis reveals that sintering between different nanoparticles in one cluster of nanoparticle is very dense, but between different sinter clusters of nano particles, very weak bridges are formed.

Comparing the different silvers with XRD (X-ray diffraction) showed that all silvers which are sinterable share the same characteristics:
1) Ψ should be below 0.0020
2) ratio of (peak intensity of diffraction peak 200 and peak intensity of diffraction peak 111) should be above 0.5
3) Crystallinity should be above 50%.

### Example 2

### Quantification of Amorphous/Crystalline Fraction of Samples

Quantification of crystallinity can be performed using a Rietveld refinement method of X-ray diffraction data of a specimen, in which the sample to be studied is mixed with a 100% crystalline compound in a known relation. For the purposes of this invention, a defined amount of silver samples were mixed with fully crystalline SiO₂ (the weight relation for both is near to 1:1). Then the X-ray diffraction pattern was measured and Rietveld analysis was performed according to methods known to those skilled in the art. From the known amount of silver and SiO₂, and the obtained silver weight fraction, the amount (and fraction) of crystalline silver was obtained. Other variations of the Rietveld refinement method, as well as different methods of determining crystalline fraction can also be used to obtain the degree of crystallinity used for the purpose of this invention.

Various modifications of the present invention, in addition to those shown and described herein, will be apparent to those skilled in the art of the above description. Such modifications are also intended to fall within the scope of the appended claims.

Patents and publications mentioned in the specification are indicative of the levels of those skilled in the art to which the invention pertains. These patents and publications are incorporated herein by reference to the same extent as if each individual application or publication was specifically and individually incorporated herein by reference.

The foregoing description is illustrative of particular embodiments of the invention, but is not meant to be a limitation upon the practice thereof. The following claims, including all equivalents thereof, are intended to define the scope of the invention.

That which is claimed is:

1. A conductive adhesive composition comprising:
sinterable metal particles dispersed in
a suitable carrier,
wherein at least a portion of said metal particles are characterized by:
having a Ψ value, as defined by X-ray diffraction, <0.0020,
having at least 50% degree of crystallinity, and
being anisotropic with respect to crystallographic direction.

2. The composition of claim 1 wherein said metal is selected from Ag, Cu, Au, Pd, Ni, In, Sn, Zn, Li, Mg, Al or Mo.

3. The composition of claim 1 wherein said metal is silver.

4. The composition of claim 1 wherein said carrier is an alcohol, an aromatic hydrocarbon, a saturated hydrocarbon, a chlorinated hydrocarbon, an ether, a polyol, an ester, a dibasic ester, kerosene, high boiling alcohols and esters thereof, glycol ethers, ketones, amides, heteroaromatic compounds, as well as mixtures of any two or more thereof.

5. The composition of claim 4 wherein said alcohol is dipropylene glycol, ethylene glycol, diethylene glycol, triethylene glycol, hexylene glycol, 1-methoxy-2-propanol, diacetone alcohol, tert-butyl alcohol, 2-ethyl-1,3-hexanediol, tridecanol, 1,2-octanediol, butyldiglycol, alpha-terpineol or beta-terpineol.

6. The composition of claim 4 wherein said ester is 2-(2-butoxyethoxy)ethyl acetate, 2,2,4-trimetyl-1,3-pentanediol diisobutyrate, 1,2-propylene carbonate, carbitol acetate, butyl carbitol acetate, butyl carbitol, butyl carbitol acetate, ethyl carbitol acetate, hexylene glycol, or dibutylphthalate.

7. The composition of claim 1 wherein said metal particles comprise in the range of about 20 up to about 98 weight percent of the composition.

8. The composition of claim 1 wherein said composition is capable of curing at a temperature in the range of 100-350° C., without the need for the application of external mechanical force.

9. A method of preparing a conductive network, said method comprising:
applying a composition according to claim 1 to a suitable substrate to bond a suitable component thereto, and thereafter
sintering said composition.

10. The method of claim 9 wherein said suitable component is a bare die.

11. The method of claim 9 wherein said sintering is carried out at a temperature in the range of 100-350° C., for a time in the range of 0.5 up to about 120 minutes.

12. The method of claim 9 wherein said sintering is carried out at a temperature in the range of 150-300° C. for a time in the range of 1 up to about 90 minutes.

13. The method of claim 12 wherein said suitable substrate is a ceramic layer.

14. The method of claim 9 wherein said suitable substrate is a lead frame.

15. A conductive network prepared by the method of claim 9.

16. The conductive network of claim 15 further comprising a substrate therefor, wherein the adhesion between said conductive network and said substrate is at least 3 kg/mm², as determined by a die shear strength measurement.

17. A method for identifying metallic powders which are sinterable, said method comprising identifying as sinterable those metallic powders which have:
a Ψ value of <0.0020,
at least 50% degree of crystallinity, and
at least a portion of said metal particles are anisotropic with respect to crystallographic direction.

18. A method for determining whether a metallic powder is sinterable, said method comprising:
measuring the Ψ value thereof, the degree of crystallinity thereof and whether or not the sample is anisotropic, and
identifying as sinterable those metallic powders which have:
a value of <0.0020,
at least 50% degree of crystallinity, and
at least a portion of said metal particles are anisotropic with respect to crystallographic direction.
